(19) United States
(12) Patent Application Publication
(10) Pub. No.: US 2018/0115301 A1
(43) Pub. Date: Apr. 26, 2018

(54) PIEZOELECTRIC VIBRATING PIECE AND PIEZOELECTRIC DEVICE

(71) Applicant: NIHON DEMPA KOGYO CO., LTD., Tokyo (JP)

(72) Inventors: Shigetaka KAGA, Saitama (JP); Yoshiro TESHIMA, Saitama (JP); Kazuhiro HIROTA, Saitama (JP)

(73) Assignee: NIHON DEMPA KOGYO CO., LTD., Tokyo (JP)

(21) Appl. No.: 15/784,209

(22) Filed: Oct. 16, 2017

(30) Foreign Application Priority Data
Oct. 26, 2016 (JP) 2016-209259

(51) Int. Cl. H03H 9/13; H02N 2/00; H01L 41/047; H01L 41/053; H01L 41/18; H03H 9/10; H03H 9/19

(52) U.S. Cl. CPC H03H 9/132; H02N 2/0045; H01L 41/047; H03H 9/19; H01L 41/18; H03H 9/10; H01L 41/053

(57) ABSTRACT

A piezoelectric vibrating piece includes a piezoelectric substrate and excitation electrodes. The piezoelectric substrate is formed in a flat plate shape and vibrates in a thickness-shear vibration mode. The excitation electrodes are disposed on respective both principal surfaces of the piezoelectric substrate. The excitation electrode includes a main thickness portion and an inclined portion. The main thickness portion has a constant thickness. The inclined portion is formed in a peripheral area of the main thickness portion. The inclined portion has a thickness that gradually decreases from a portion contacting the main thickness portion to an outermost periphery of the excitation electrode. An inclination width as a width of the inclined portion has a length that is equal to or more than 0.5 times and equal to or less than three times of a flexural wavelength. The flexural wavelength is a wavelength of a flexure vibration as an unnecessary vibration.

### CROSS-REFERENCE TO RELATED APPLICATIONS

This application is based on and claims priority under 35 U.S.C. § 119 to Japanese Patent Application No. 2016-209259, filed on Oct. 26, 2016, the entire content of which is incorporated herein by reference.

### TECHNICAL FIELD

This disclosure relates to a piezoelectric vibrating piece and a piezoelectric device, and the piezoelectric vibrating piece includes an inclined portion in a peripheral area of an excitation electrode.

### DESCRIPTION OF THE RELATED ART

A piezoelectric vibrating piece including an excitation electrode on a piezoelectric substrate is formed in a convex shape having a thin thickness in a peripheral area of the piezoelectric substrate, and thus confines vibration energy, thereby ensuring the reduced unnecessary vibration. However, forming the piezoelectric substrate in the convex shape causes a problem of a labor and cost increase in processing.

In contrast to this, Japanese Unexamined Patent Application Publication No. 2002-217675 describes a technical content that while a piezoelectric substrate still has a flat plate shape, a peripheral area of an excitation electrode is formed in an inclined surface shape where a thickness of the excitation electrode gradually decreases, thus saving the labor and cost of the processing of the piezoelectric substrate.

However, even when the inclined surface shape as described in Japanese Unexamined Patent Application Publication No. 2002-217675 is formed, it has been found that the effect that reduces an unnecessary vibration substantially differs depending on a dimension of the inclined surface shape. That is, there has been a problem where simply forming the peripheral area of the excitation electrode in an inclined surface shape does not ensure the sufficiently reduced unnecessary vibration.

A need thus exists for a piezoelectric vibrating piece and a piezoelectric device which are not susceptible to the drawback mentioned above.

### SUMMARY

According to a first aspect of this disclosure, there is provided a piezoelectric vibrating piece that includes a piezoelectric substrate and excitation electrodes. The piezoelectric substrate is formed in a flat plate shape and vibrates in a thickness-shear vibration mode. The excitation electrode is respectively disposed on both principal surfaces of the piezoelectric substrate. The excitation electrode includes a main thickness portion and an inclined portion. The main thickness portion has a constant thickness. The inclined portion is formed in a peripheral area of the main thickness portion. The inclined portion has a thickness that gradually decreases from a portion contacting the main thickness portion to an outermost periphery of the excitation electrode. An inclination width as a width of the inclined portion has a length that is equal to or more than 0.5 times and equal to or less than three times of a flexural wavelength. The flexural wavelength is a wavelength of a flexure vibration as an unnecessary vibration.

### BRIEF DESCRIPTION OF THE DRAWINGS

The foregoing and additional features and characteristics of this disclosure will become more apparent from the following detailed description considered with reference to the accompanying drawings, wherein:

FIG. 1A is a perspective view of a piezoelectric device 100.

FIG. 1B is a perspective view of the piezoelectric device 100 from which a lid 120 is removed.

FIG. 2A is a plan view of a piezoelectric vibrating piece 140.

FIG. 2B is a sectional drawing taken along the line IIB-IIB in FIG. 2A.

FIG. 3A is an explanatory drawing of an M-SC-cut quartz-crystal material.

FIG. 3B is a graph showing relationships between inclination widths and losses (1/Q) of vibration energy of main vibrations of the piezoelectric vibrating piece 140 and a piezoelectric vibrating piece 240.

FIG. 4A is a plan view of a piezoelectric vibrating piece 340.

FIG. 4B is a graph showing relationships between inclination widths and losses (1/Q) of vibration energy of main vibrations of the piezoelectric vibrating piece 140 and the piezoelectric vibrating piece 340.

FIG. 5 is a graph showing a relationship between an inclination width and a loss (1/Q) of vibration energy of a main vibration of a piezoelectric vibrating piece 440.

FIG. 6A is a partial sectional drawing of a piezoelectric vibrating piece 140a.

FIG. 6B is a partial sectional drawing of a piezoelectric vibrating piece 140b.

FIG. 6C is a partial sectional drawing of a piezoelectric vibrating piece 140c.

### DETAILED DESCRIPTION

The embodiments of this disclosure will be described in detail with reference to the drawings. The embodiments in the following description do not limit the scope of the disclosure unless otherwise stated.

### First Embodiment

[Configuration of Piezoelectric Device 100]

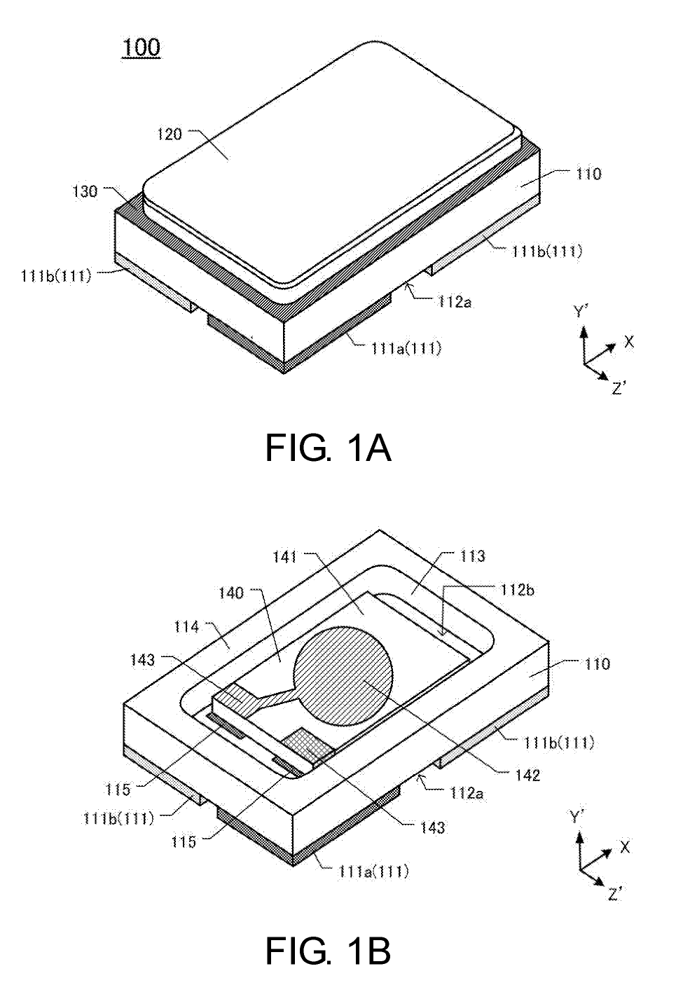

FIG. 1A is a perspective view of a piezoelectric device 100. The piezoelectric device 100 mainly includes a base 110, a lid 120, and a piezoelectric vibrating piece 140 (see FIG. 1B) that vibrates at a predetermined vibration frequency. An outer shape of the piezoelectric device 100 is, for example, formed in an approximately rectangular parallelepiped shape. The piezoelectric vibrating piece 140 is formed using an AT-cut quartz-crystal material that vibrates in a thickness-shear vibration mode as a base material. The AT-cut quartz-crystal material is formed having a principal surface (X-Z surface) that is inclined by 35° 15′ from a Z-axis toward a −Y-axis direction about an X-axis with respect to a Y-axis of a crystallographic axis (XYZ). In the following descriptions, a new axis on which the AT-cut quartz-crystal material is inclined is denoted as a Y′-axis and a Z′-axis. The piezoelectric device 100 illustrated in FIG. 1A is formed such that a longitudinal direction is an X-axis direction, a height direction of the piezoelectric device 100 is a Y′-axis direction, and a direction perpendicular to the X-axis direction and the Y′-axis direction is a Z′-axis direction.

Mounting terminals 111 are disposed on a mounting surface 112a. The mounting surface 112a is a surface on a −Y′-axis side of the base 110 and is a surface on which the piezoelectric device 100 is mounted. The mounting terminals 111 includes hot terminals 111a that are terminals connected to the piezoelectric vibrating piece 140, and terminals (hereinafter temporarily referred to as grounding terminals) 111b that can be used for grounding. On the base 110, the respective hot terminals 111a are disposed at a corner of a −Z-axis side on the +X-axis side and a corner of the +Z-axis side on a −X-axis side that are on the mounting surface 112a. The respective grounding terminals 111b are disposed at a corner of the +Z-axis side on the +X-axis side and a corner of the −Z-axis side on the −X-axis side that are on the mounting surface 112a. On a surface of the base 110 on the +Y-axis side, a cavity 113 that is a space to place the piezoelectric vibrating piece 140 is disposed (see FIG. 1B). The cavity 113 is sealed with the lid 120 via a sealing material 130.

FIG. 1B is a perspective view of the piezoelectric device 100 from which the lid 120 is removed. The cavity 113, which is disposed on the surface of the base 110 on the +Y′-axis side, is surrounded by a placement surface 112b and a sidewall 114. The placement surface 112b is a surface on an opposite side of the mounting surface 112a and on which the piezoelectric vibrating piece 140 is placed. The sidewall 114 is disposed in a peripheral area of the placement surface 112b. On the placement surface 112b, a pair of connection electrodes 115 that are electrically connected to the hot terminals 111a is disposed.

The piezoelectric vibrating piece 140 includes a piezoelectric substrate 141, excitation electrodes 142, and extraction electrodes 143. The piezoelectric substrate 141 is formed in a flat plate shape and vibrates in a thickness-shear vibration mode. The excitation electrodes 142 are disposed on respective principal surfaces of the piezoelectric substrate 141 on the +Y′-axis side and the −Y′-axis side. The extraction electrodes 143 are extracted from the respective excitation electrodes 142 to both ends of sides of the piezoelectric substrate 141 on the −X-axis side. The excitation electrode 142 disposed on a surface of the piezoelectric substrate 141 on the +Y′-axis side and the excitation electrode 142 disposed on a surface of the piezoelectric substrate 141 on the −Y′-axis side are formed to have identical shapes and identical sizes, and are disposed such that the excitation electrodes 142 entirely and mutually overlap in the Y′-axis direction. The piezoelectric vibrating piece 140 is placed on the placement surface 112b such that the extraction electrodes 143 and the connection electrodes 115 are electrically connected via conductive adhesives (not illustrated).

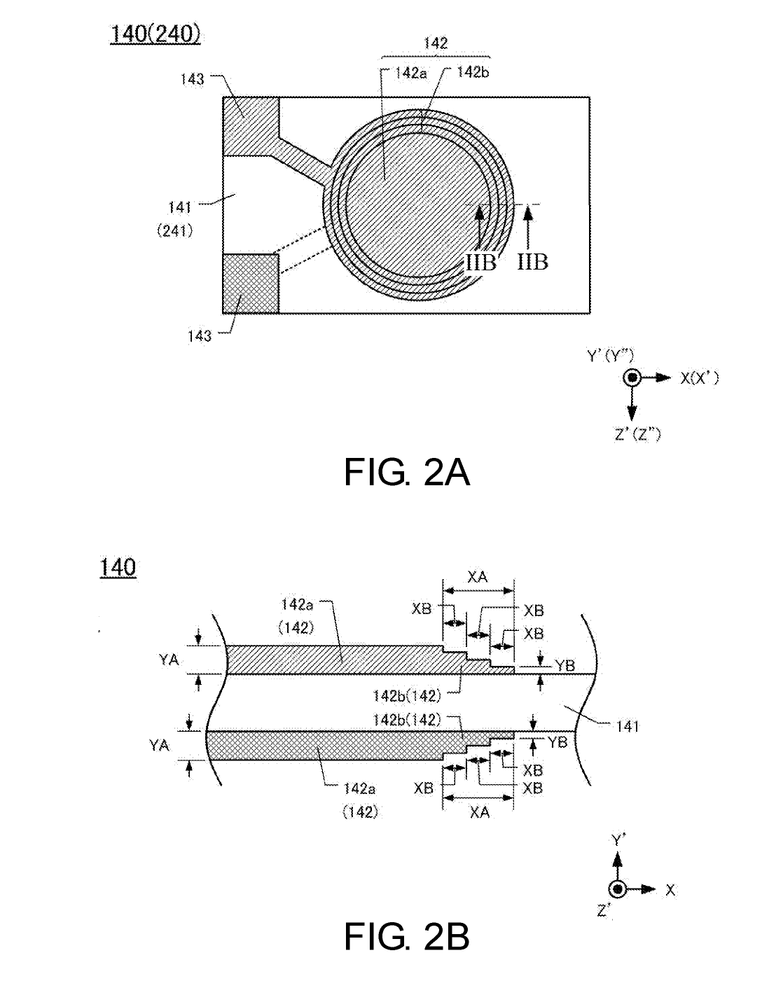

FIG. 2A is a plan view of the piezoelectric vibrating piece 140. The piezoelectric substrate 141 is a flat-plate shaped base plate that has a rectangular shaped plane having long sides extending in the X-axis direction and short sides extending in the Z′-axis direction. The excitation electrodes 142, which are disposed on the principal surfaces of the piezoelectric substrate 141 on the +Y′-axis side and the −Y′-axis side, are formed in circular shapes. The excitation electrodes 142 each include a main thickness portion 142a and an inclined portion 142b. The main thickness portion 142a is formed to have a constant thickness. The inclined portion 142b is formed in a peripheral area of the main thickness portion 142a and formed so as to have a constant width and a thickness that is gradually thinned from a portion contacting with the main thickness portion 142a to an outermost periphery of the excitation electrode 142. FIG. 2A illustrates a piezoelectric vibrating piece in the case where the piezoelectric substrate is made of an M-SC (Modified-SC)-cut quartz-crystal material as a piezoelectric vibrating piece 240. The piezoelectric vibrating piece 240 is described later.

FIG. 2B is a sectional drawing taken along the line IIB-IIB in FIG. 2A. On the piezoelectric vibrating piece 140, the main thickness portions 142a and the inclined portions 142b, which are disposed on the surfaces of the piezoelectric substrate 141 on the +Y′-axis side and the −Y′-axis side, are disposed so as to entirely and mutually overlap in the Y′-axis direction. The inclined portion 142b is formed such that the thickness is gradually thinned from the main thickness portion 142a side to the outermost periphery of the excitation electrode 142 by forming four level differences. The inclined portion 142b is formed to have a width of XA from the main thickness portion 142a side to the outermost periphery of the excitation electrode 142 and a width of XB between the respective level differences. That is, as illustrated in FIG. 2B, the width XA is formed to have a length that is three times of the width XB. The main thickness portion 142a of the excitation electrode 142 is formed to have a thickness of YA. Each of the level differences of the inclined portion 142b is formed to have a height of YB. Therefore, the thickness YA has a thickness that is four times of the height YB.

The piezoelectric substrate 141 used in the piezoelectric vibrating piece 140 is the flat-plate shaped base plate on which processing, such as bevel processing or convex processing, is not performed. In spite of this, the excitation electrode including the main thickness portion that is formed to have a predetermined thickness and the inclined portion that is formed to have a predetermined width in the peripheral area of the main thickness portion ensures preventing the loss of the vibration energy and reducing the unnecessary vibration.

[Loss of Vibration Energy of Piezoelectric Vibrating Piece 140 and Piezoelectric Vibrating Piece 240]

The following describes a simulation result regarding a loss of vibration energy of the piezoelectric vibrating piece 140 with comparison with the piezoelectric vibrating piece 240 that includes a piezoelectric substrate made of an M-SC-cut quartz-crystal material.

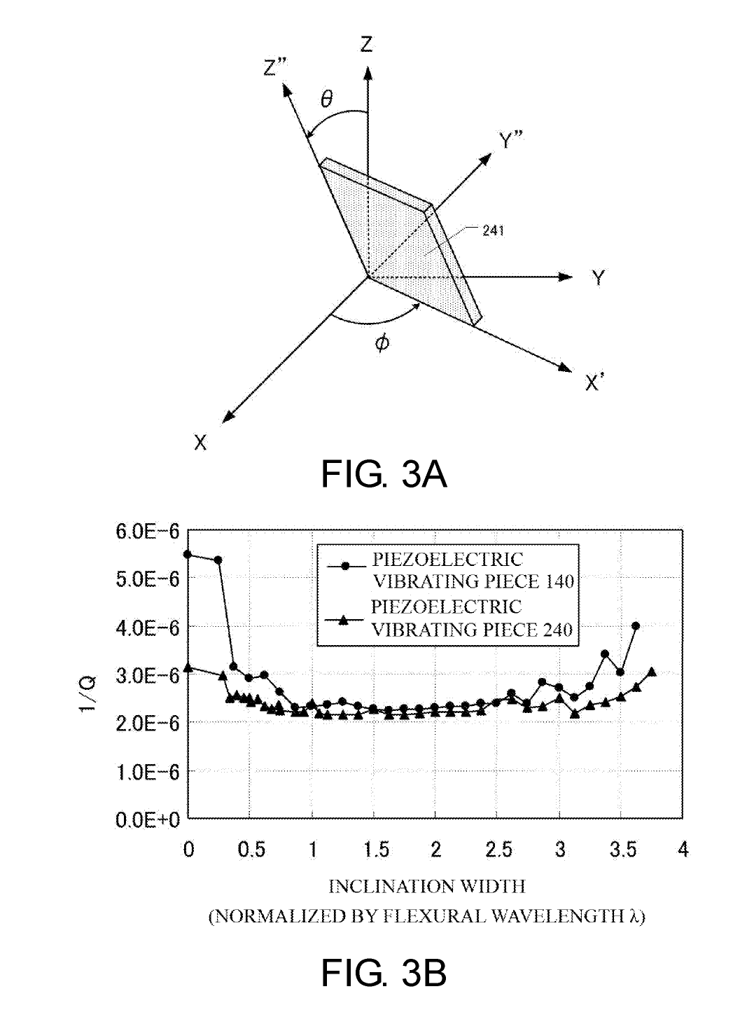

FIG. 3A is an explanatory drawing of the M-SC-cut quartz-crystal material. FIG. 3A denotes crystallographic axes for a crystal as an X-axis, a Y-axis, and a Z-axis. The M-SC-cut quartz-crystal material is one type of doubly rotated cut quartz-crystal materials, and corresponds to an X′-Z″-cut plate. The X′-Z″-cut plate is obtained by rotating an X-Z-cut plate of the crystal about the Z-axis of the crystal by ϕ degree to generate an X′-Z-cut plate and further rotating the X′-Z-cut plate about an X′-axis by θ degree. In the case of the M-SC-cut, ϕ is approximately 24 degrees, and θ is approximately 34 degrees. FIG. 3A denotes new axes for the crystal element generated by the above-described doubly rotated as the X′-axis, a Y″-axis, and a Z″-axis. The doubly rotated cut quartz-crystal material is a quartz-crystal material that includes a shear displacement that propagates in a thickness direction, what is called, a quartz-crystal material who has the main vibration of C mode and B mode. Similarly to an AT-cut, the vibrations in these C mode and B mode are classified into the thickness-shear vibration.

FIG. 2A also illustrates a plan view of the piezoelectric vibrating piece 240. The piezoelectric vibrating piece 240 is a piezoelectric vibrating piece where, in the piezoelectric vibrating piece 140, the piezoelectric substrate 141 is replaced by a piezoelectric substrate 241 that is made of an M-SC-cut quartz-crystal material and has an outer shape and a size identical to the piezoelectric substrate 141. The configuration of other parts is identical to the piezoelectric vibrating piece 140. The piezoelectric vibrating piece 240 is formed to have long sides extending in the X′-axis and short sides extending in the Z″-axis.

FIG. 3B is a graph showing relationships between inclination widths and losses (1/Q) of vibration energy of main vibrations of the piezoelectric vibrating piece 140 and the piezoelectric vibrating piece 240. As an analysis model, FIG. 3B shows calculation results of simulations in the case of a model where the whole excitation electrodes are made of gold (Au), the main thickness portions 142a have film thicknesses YA of 140 nm, and a frequency of a main vibration is 26 MHz. On the piezoelectric vibrating piece, an unnecessary vibration that is a vibration different from the main vibration and unintended in design is generated along with the main vibration (for example, the C mode). In the piezoelectric vibrating piece including the piezoelectric substrate that is made of the quartz-crystal material such as AT-cut and SC-cut quartz-crystal materials and vibrates in a thickness-shear vibration mode, an effect caused especially by a flexure vibration is large as an unnecessary vibration. In the graph in FIG. 3B, a horizontal axis indicates inclination widths that are normalized by a flexural wavelength λ as the wavelength of this flexure vibration. Therefore, even in identical scales, the inclination widths shown in the graph in FIG. 3B are different between actual dimensions of the inclination widths of the piezoelectric vibrating piece 140 and the piezoelectric vibrating piece 240. For example, when vibrations at a vibration frequency of 26 MHz are set as the main vibration, the flexural wavelength λ of the piezoelectric vibrating piece 140 including the piezoelectric substrate made of the AT-cut quartz-crystal material is approximately 100 μm, and the flexural wavelength λ, of the piezoelectric vibrating piece 240 including the piezoelectric substrate made of the M-SC-cut quartz-crystal material is approximately 110 μm. In this case, in the graph in FIG. 3B, the actual dimension of the inclination width expressed by “1” is 1×λ. In the piezoelectric vibrating piece 140, the inclination width is 1×λ=approximately 100 μm. In the piezoelectric vibrating piece 240, the inclination width is 1×λ=approximately 110 μm.

In the graph in FIG. 3B, a vertical axis indicates a reciprocal of a Q factor indicating a loss of vibration energy of a main vibration. In FIG. 3B, a black circle denotes the piezoelectric vibrating piece 140, which includes the piezoelectric substrate 141 made of the AT-cut quartz-crystal material, and a black triangle denotes the piezoelectric vibrating piece 240, which includes the piezoelectric substrate 241 made of the M-SC-cut quartz-crystal material.

In FIG. 3B, both the piezoelectric vibrating piece 140 and the piezoelectric vibrating piece 240 have 1/Q that indicates the loss of the vibration energy equal to or less than 3.0×10⁻⁶ (indicated as “3.0E-6” in FIG. 3B), which is low, in a range where the inclination widths that are normalized by the flexural wavelength λ, are from approximately “0.5” to “3.”. That is, it is found that the loss of the vibration energy is reduced in the case where the inclination width is formed to have a length that is equal to or more than 0.5 times and equal to or less than three times of the flexural wavelength λ. Especially, the piezoelectric vibrating piece 140 and the piezoelectric vibrating piece 240 have low magnitudes of 1/Q, and further, their variations are reduced in a range where the inclination widths that are not normalized by the flexural wavelength λ are from “1” to “2.5.”. That is, it is found that the loss of the vibration energy stably lowers in the case where the inclination width has a length that is one time to 2.5 times of the flexural wavelength λ.

The vibration energy is converted into a flexure vibration in, mainly, an end portion of the excitation electrode, and thus the flexure vibration superimposes on the main vibration. The flexure vibration vibrates in the entire piezoelectric vibrating piece, and thus a conductive adhesive to which the piezoelectric vibrating piece is held absorbs the vibration energy. The loss of energy due to such flexure vibration leads to the loss of the vibration energy. The piezoelectric vibrating piece 140 and the piezoelectric vibrating piece 240 include the inclined portions having the inclination widths with the lengths that are equal to or more than 0.5 times and equal to or less than three times of the flexural wavelength λ, especially, having the inclination widths with lengths that are equal to or more than one time and equal to or less than 2.5 times of the flexural wavelength λ, thus reducing the generation of flexure vibration. It is considered that this ensures the reduced loss of the vibration energy.

In FIG. 3B, both the piezoelectric vibrating pieces of the piezoelectric vibrating piece 140 and the piezoelectric vibrating piece 240 have low 1/Q in a range where the inclination widths that are normalized by the flexural wavelength λ is from“0.5” to “3,” at the same time, there is not much difference in the values of 1/Q between the piezoelectric vibrating piece 140 and the piezoelectric vibrating piece 240. That is, when taking the inclination width normalized by the flexural wavelength λ into consideration, it is considered that a trend and the value of 1/Q are stable regardless of a difference of a piezoelectric material employed for the piezoelectric substrate. Therefore, while FIG. 3B shows examples of the AT-cut quartz-crystal material and the M-SC-cut quartz-crystal material, the quartz-crystal material is not limited to these quartz-crystal materials. When another quartz-crystal material that vibrates in a thickness-shear vibration mode, such as an SC-cut and an IT-cut quartz-crystal materials, is employed, or also when another piezoelectric material that vibrates in a thickness-shear vibration mode, such as LT (lithium tantalate) and piezoelectric ceramic, is employed for the piezoelectric substrate, it is considered that 1/Q lowers in a range of the inclination width similar to the piezoelectric vibrating piece 140 and the piezoelectric vibrating piece 240.

### Second Embodiment

While in the first embodiment, the case where the excitation electrode is formed in a circular shape has been described, the reduced loss of the vibration energy is ensured even when the planar shape of the excitation electrode is formed into a shape other than the circular shape when the inclined portion is formed to have a predetermined width. The following describes the case where the excitation electrode is formed into a shape other than the circular shape.

[Configuration of Piezoelectric Vibrating Piece 340]

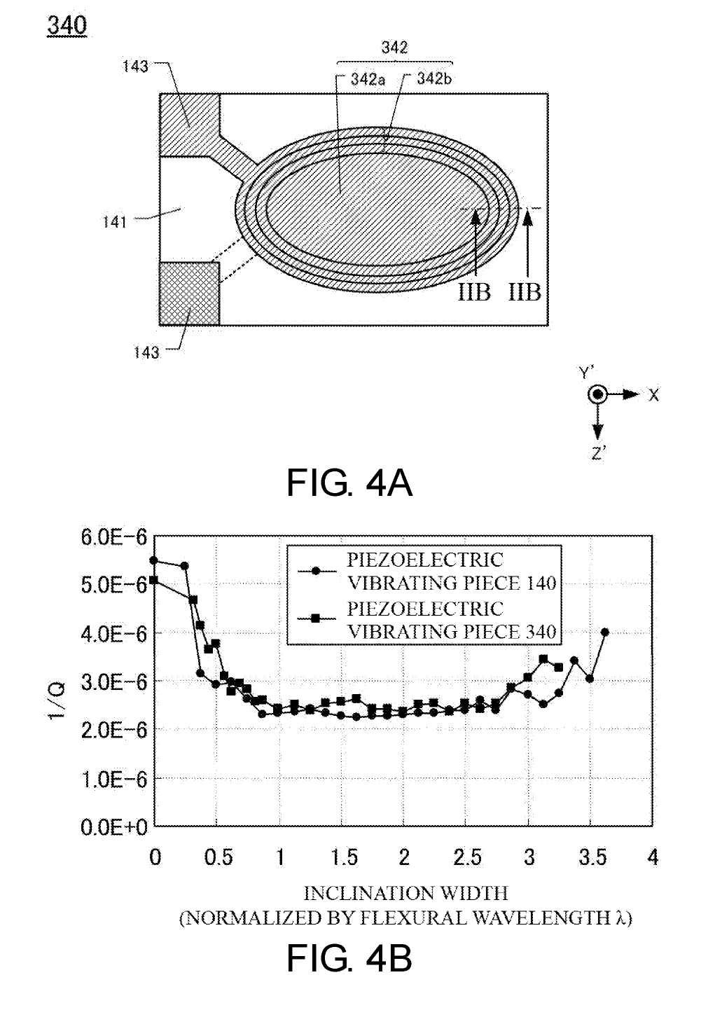

FIG. 4A is a plan view of a piezoelectric vibrating piece 340. The piezoelectric vibrating piece 340 includes the piezoelectric substrate 141, excitation electrodes 342, and the extraction electrodes 143. The excitation electrodes 342 are disposed on the respective principal surfaces of the piezoelectric substrate 141 on the +Y′-axis side and the −Y′-axis side. The extraction electrodes 143 are extracted from the respective excitation electrodes 342 to both the ends of the sides of the piezoelectric substrate 141 on the −X-axis side. The excitation electrode 342 is formed in an elliptical shape whose long axis extends in the X-axis direction and short axis extends in the Z′-axis direction. The excitation electrode 342 includes a main thickness portion 342a and an inclined portion 342b. The main thickness portion 342a is formed to have a constant thickness. The inclined portion 342b is formed in a peripheral area of the main thickness portion 342a and formed so as to have a constant width and a thickness that is gradually thinned from portion contacting with the main thickness portion 342a to an outermost periphery of the excitation electrode 342. The cross section taken along the line IIB-IIB in FIG. 4A is formed in a shape identical to the sectional drawing in FIG. 2B, and a thickness of the excitation electrode and respective dimensions of the inclined portion are identical to the dimensions illustrated in FIG. 2B.

[Loss of Vibration Energy of Piezoelectric Vibrating Piece 140 and Piezoelectric Vibrating Piece 340]

With a comparison between the piezoelectric vibrating piece 140, which includes the excitation electrode formed in a circular shape, and the piezoelectric vibrating piece 340, which includes the excitation electrode formed in an elliptical shape, the following describes simulation results regarding the losses of the vibration energy of the piezoelectric vibrating piece 140 and the piezoelectric vibrating piece 340.

FIG. 4B is a graph showing relationships between inclination widths and losses (1/Q) of vibration energy of main vibrations of the piezoelectric vibrating piece 140 and the piezoelectric vibrating piece 340. As an analysis model, FIG. 4B shows calculation results of simulations in the case of a model where the whole excitation electrodes are made of gold (Au), the main thickness portions have the film thicknesses of 140 nm, and a frequency of a main vibration is 26 MHz. In the graph in FIG. 4B, a horizontal axis indicates inclination widths that are normalized by the flexural wavelength λ that is the wavelength of the flexure vibration as an unnecessary vibration. In the graph in FIG. 4B, a vertical axis indicates a reciprocal of a Q factor indicating a loss of vibration energy of a main vibration. In FIG. 4B, a black circle denotes the piezoelectric vibrating piece 140, and a black square denotes the piezoelectric vibrating piece 340.

When both the piezoelectric vibrating piece 140 and the piezoelectric vibrating piece 340 have the inclination widths that are normalized by the flexural wavelength and then are in the range from “0.5” to “3,” FIG. 4B shows the low values of 1/Q that indicate the losses of the vibration energy and are equal to or less than 3.0×10⁻⁶ (indicated as “3.0E-6” in FIG. 4B). That is, it is found that the loss of the vibration energy is reduced in the case where the inclination width is formed to have a length that is equal to or more than 0.5 times and equal to or less than three times of the flexural wavelength λ. Especially, when the piezoelectric vibrating piece 140 and the piezoelectric vibrating piece 340 have the inclination widths that are normalized by the flexural wavelength λ and then are in the range from “1” to “2.5,” the values of 1/Q are low, and further, their variations are reduced. That is, it is found that the loss of the vibration energy stably lowers in the case where the inclination width has a length that is one time to 2.5 times of the flexural wavelength λ.

In FIG. 4B, when both the piezoelectric vibrating pieces of the piezoelectric vibrating piece 140 and the piezoelectric vibrating piece 240 have the inclination widths that are normalized by the flexural wavelength λ and then are in the range from“0.5” to “3,” 1/Q lowers and the values of 1/Q do not gradually have a large difference also between the piezoelectric vibrating piece 140 and the piezoelectric vibrating piece 340. Therefore, when the inclination width normalized by the flexural wavelength λ is in the range from“0.5” to “3,” it is considered that a trend and the value of 1/Q are stable regardless of a difference of a shape of the excitation electrode. That is, while FIG. 4B shows examples of the excitation electrodes, which are formed in a circular shape and an elliptical shape, the shape is not limited to these shapes. Even when the excitation electrode is formed in another shape, such as a square shape, it is considered that the similar inclination width lowers 1/Q.

### Third Embodiment

While in the first embodiment and the second embodiment, the cases where the main thickness portion of the excitation electrode is formed to have a thickness of 140 nm are considered, the main thickness portion may be formed to have a thickness having another value. The following describes a case where a main thickness portion has a different thickness.

[Configuration and Loss of Vibration Energy of Piezoelectric Vibrating Piece 440]

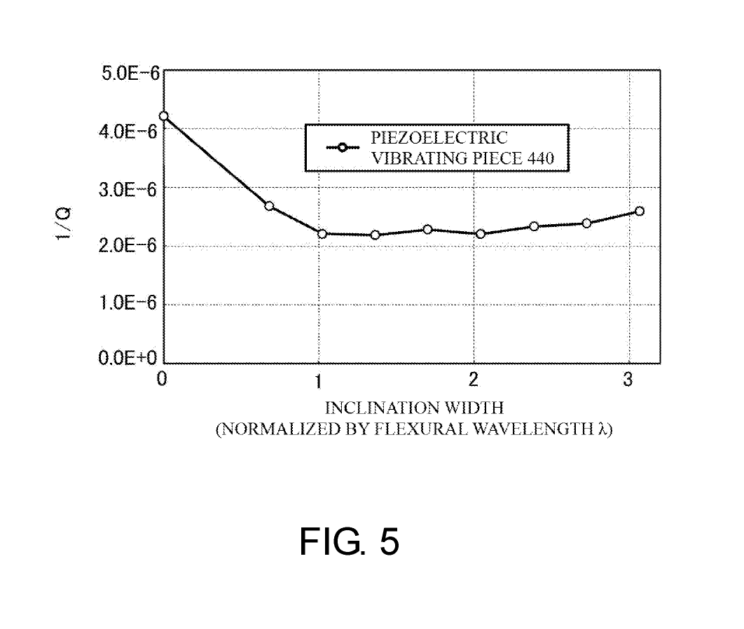

FIG. 5 is a graph showing a relationship between an inclination width and a loss (1/Q) of vibration energy of a main vibration of a piezoelectric vibrating piece 440. The piezoelectric vibrating piece 440 is a piezoelectric vibrating piece where a main thickness portion is formed to have a thickness YA of 100 nm in the piezoelectric vibrating piece 240 (that is, an M-SC-cut piezoelectric vibrating piece) illustrated in FIG. 2A and FIG. 2B. This forms a thickness of a thickness YB to be 25 nm. Other shapes and sizes are identical to those of the piezoelectric vibrating piece 240.

FIG. 5 shows experimental results until the inclination width normalized by the flexural wavelength λ just exceeds 3. As apparent from FIG. 5, even when the film thickness of the electrode is changed with respect to the first embodiment when the inclination width is formed to have a length that is equal to or more than 0.5 times and equal to or less than three times of the flexural wavelength λ, it is found that the loss of the vibration energy is reduced. Furthermore, when the inclination width is formed to have a length that is equal to or more than one time and equal to or less than 2.5 times of the flexural wavelength λ, it is found that the loss of the vibration energy is further reduced. Therefore, even when the film thickness of the electrode is changed, it is found to be effective to make the inclination width be in a range equal to or more than 0.5 times and equal to or less than three times of the flexural wavelength λ, preferably, equal to or more than one time and equal to or less than 2.5 times. This trend can be confirmed also when the film thickness of the excitation electrode is in a range at least from 70 nm to 200 nm.

### Fourth Embodiment

While in the first embodiment to the third embodiment, the simulation results have been shown, an inclined portion of an actual excitation electrode can be formed using various methods. The following describes a piezoelectric vibrating piece 140a, a piezoelectric vibrating piece 140b, and a piezoelectric vibrating piece 140c as actual formation examples of the piezoelectric vibrating piece 140 illustrated in FIG. 2A and FIG. 2B.

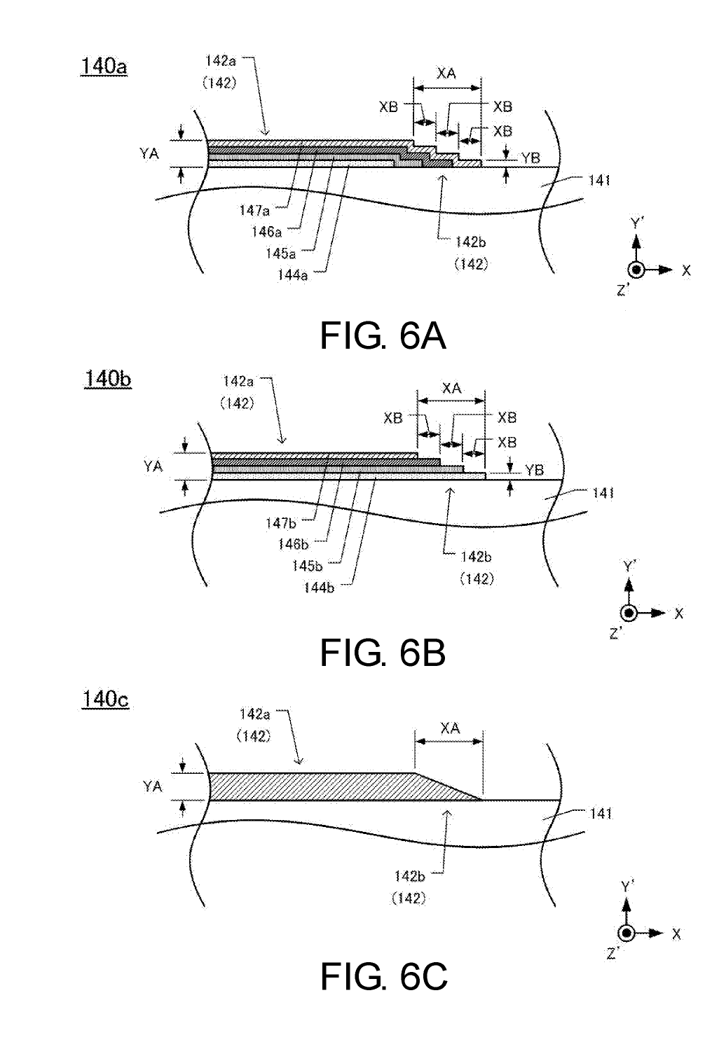

FIG. 6A is a partial sectional drawing of the piezoelectric vibrating piece 140a. FIG. 6A is a partial sectional drawing including a cross section corresponding to the cross section taken along the line IIB-IIB in FIG. 2A. The excitation electrode 142 of the piezoelectric vibrating piece 140a is formed to include a first layer 144a, a second layer 145a, a third layer 146a, and a fourth layer 147a. The second layer 145a is formed so as to cover the first layer 144a. The third layer 146a is formed so as to cover the second layer 145a. The fourth layer 147a is formed so as to cover the third layer 146a. These first layer 144a to fourth layer 147a can be formed, for example, by sputtering or evaporation. As illustrated in FIG. 6A, the laminated layers are formed to have areas that gradually increase, thus ensuring forming the inclinations of the inclined portion 142b. While FIG. 6A illustrates only four layers, FIG. 6A omits the illustration of a base layer, such as a chrome film, that is ordinarily disposed in order to ensure adhesion of the piezoelectric substrate 141 and an excitation electrode metal.

FIG. 6B is a partial sectional drawing of the piezoelectric vibrating piece 140b. FIG. 6B is a partial sectional drawing including a cross section corresponding to the cross section taken along the line IIB-IIB in FIG. 2A. The excitation electrode 142 of the piezoelectric vibrating piece 140b is formed to include a first layer 144b, a second layer 145b, a third layer 146b, and a fourth layer 147b. The second layer 145b is formed to have an area smaller than the first layer 144b on a surface of the first layer 144b. The third layer 146b is formed to have an area smaller than the second layer 145b on a surface of the second layer 145b. The fourth layer 147b is formed to have an area smaller than the third layer 146b on a surface of the third layer 146b. These first layer 144b to fourth layer 147b can be formed, for example, by sputtering or evaporation. As illustrated in FIG. 6B, in contrast to the case of FIG. 6A, the laminated layers formed to have the areas that gradually decrease ensures forming the inclinations of the inclined portion 142b.

FIG. 6C is a partial sectional drawing of the piezoelectric vibrating piece 140c. FIG. 6C is a partial sectional drawing including a cross section corresponding to the cross section taken along the line IIB-IIB in FIG. 2A. The inclination of the inclined portion 142b of the excitation electrode 142 may be formed of an inclined surface illustrated in FIG. 6C instead of the level differences. Such inclined surface of the inclined portion 142b can be formed by, for example, adjusting a thickness of a resist using a photolithography technology or cutting a part of the excitation electrode by, for example, ion beam trimming after a film formation of the excitation electrode, so as to form an inclined surface.

For example, while in the above-described embodiments, the level difference of the inclined portion has four stairs, the level difference is not limited to four stairs and may be more or less than this. Also, the above-described embodiments may be implemented using various combinations.

A piezoelectric vibrating piece of a second aspect according to the first aspect is configured as follows. The inclination width is formed to have a length that is one time to 2.5 times of the flexural wavelength.

The piezoelectric vibrating pieces of third aspects according to the first aspect and the second aspect are configured as follows. The main thickness portion is formed to have a thickness that is between 70 nm and 200 nm.

The piezoelectric vibrating pieces of fourth aspects according to the first aspect to the third aspect are configured as follows. The outer shape of the excitation electrode is formed to have a circular shape or an elliptical shape.

The piezoelectric device of a fifth aspect includes the piezoelectric vibrating pieces according to the first aspect to the fourth aspect and a package on which the piezoelectric vibrating piece is placed.

The piezoelectric vibrating piece and the piezoelectric device according to the embodiments ensures the reduced occurrence of an unnecessary vibration.

The principles, preferred embodiment and mode of operation of the present invention have been described in the foregoing specification. However, the invention which is intended to be protected is not to be construed as limited to the particular embodiments disclosed. Further, the embodiments described herein are to be regarded as illustrative rather than restrictive. Variations and changes may be made by others, and equivalents employed, without departing from the spirit of the present invention. Accordingly, it is expressly intended that all such variations, changes and equivalents which fall within the spirit and scope of the present invention as defined in the claims, be embraced thereby.

What is claimed is:

1. A piezoelectric vibrating piece, comprising:
a piezoelectric substrate formed in a flat plate shape, the piezoelectric substrate vibrating in a thickness-shear vibration mode; and
an excitation electrode, respectively disposed on both principal surfaces of the piezoelectric substrate,
wherein the excitation electrode includes a main thickness portion and an inclined portion,
the main thickness portion having a constant thickness,
the inclined portion being formed in a peripheral area of the main thickness portion, the inclined portion having a thickness that gradually decreases from a portion contacting the main thickness portion to an outermost periphery of the excitation electrode, and
an inclination width as a width of the inclined portion has a length that is equal to or more than 0.5 times and equal to or less than three times of a flexural wavelength, the flexural wavelength being a wavelength of a flexure vibration as an unnecessary vibration.

2. The piezoelectric vibrating piece according to claim 1, wherein
the inclination width has a length that is one time to 2.5 times of the flexural wavelength.

3. The piezoelectric vibrating piece according to claim 1, wherein
the main thickness portion has a thickness that is between 70 nm and 200 nm.

4. The piezoelectric vibrating piece according to claim 1, wherein
an outer shape of the excitation electrode is formed in a circular shape or an elliptical shape.

5. A piezoelectric device, comprising:
the piezoelectric vibrating piece according to claim 1; and
a package, on which the piezoelectric vibrating piece is placed.
